(19) United States
(12) Patent Application Publication
(10) Pub. No.: US 2023/0178520 A1
(43) Pub. Date: Jun. 8, 2023

(54) LIGHT-EMITTING DIODE PACKAGE AND MANUFACTURING METHOD THEREOF

(71) Applicant: Unimicron Technology Corp., Taoyuan City (TW)

(72) Inventors: Wen-Yu Lin, Taichung City (TW); Kai-Ming Yang, Hsinchu County (TW); Chen-Hao Lin, Keelung City (TW)

(73) Assignee: Unimicron Technology Corp., Taoyuan City (TW)

(21) Appl. No.: 17/571,543

(22) Filed: Jan. 10, 2022

(30) Foreign Application Priority Data
Dec. 8, 2021 (TW) 110145768

(51) Int. Cl. H01L 25/075; H01L 33/00; H01L 23/00

(52) U.S. Cl. CPC H01L 25/0753; H01L 33/0093; H01L 24/19; H01L 24/94; H01L 24/20; H01L 33/62

(57) ABSTRACT

A light-emitting diode package includes a redistribution layer, a light-emitting diode, a first dielectric layer, a plurality of wavelength conversion structures, and a transparent encapsulant. The light-emitting diode is disposed on and electrically connected to the redistribution layer. The light-emitting diode includes a first light-emitting diode, a second light-emitting diode, and a third light-emitting diode. The first dielectric layer is disposed on the redistribution layer and covers the light-emitting diode. The wavelength conversion structures are disposed on the first dielectric layer and respectively in contact with the second light-emitting diode and the third light-emitting diode. The transparent encapsulant is disposed on the first dielectric layer and covers the plurality of wavelength conversion structures. In addition, a manufacturing method of the light-emitting diode package is provided.

### CROSS-REFERENCE TO RELATED APPLICATION

This application claims the priority benefit of Taiwan application serial no. 110145768, filed on Dec. 8, 2021. The entirety of the above-mentioned patent application is hereby incorporated by reference herein and made a part of this specification.

### BACKGROUND OF THE INVENTION

### Field of the Invention

The invention relates to a light-emitting diode package and a manufacturing method thereof, and more particularly to a light-emitting diode package and a manufacturing method thereof that may avoid the issues of die shift and optical interference.

### Description of Related Art

Generally, in the manufacturing method of a light-emitting diode package, one of the main techniques is the use of a pick-and-place method to perform the mass transfer of light-emitting diodes. In particular, the vacuum suction method using a vacuum suction tube is a commonly used pick-and-place method. However, since the physical limit of light-emitting diodes that may be sucked by the vacuum suction tube is 80 μm, micro light-emitting diodes (uLED) less than 50 μm may not be suitable for the vacuum suction method. Moreover, even after the mass transfer of sub-millimeter light-emitting diodes (mini LED) to a temporary substrate by vacuum suction, processes using an encapsulation gel (such as an epoxy molding compound (EMC)) may cause the mini LEDs to have die shift issues.

### SUMMARY OF THE INVENTION

The invention provides a light-emitting diode package and a manufacturing method thereof that may be suitable for micro light-emitting diode packaging and may avoid the issues of chip displacement and optical interference.

A light-emitting diode package of the invention includes a redistribution layer, a light-emitting diode, a first dielectric layer, a plurality of wavelength conversion structures, and a transparent encapsulant. The light-emitting diode is disposed on and electrically connected to the redistribution layer. The light-emitting diode includes a first light-emitting diode, a second light-emitting diode, and a third light-emitting diode. The first dielectric layer is disposed on the redistribution layer and covers the light-emitting diode. The plurality of wavelength conversion structures are disposed on the second light-emitting diode and the third light-emitting diode and respectively in contact with the second light-emitting diode and the third light-emitting diode. The transparent encapsulant is disposed on the first dielectric layer and covers the plurality of wavelength conversion structures.

In an embodiment of the invention, the light-emitting diode package does not have a native epitaxy substrate.

In an embodiment of the invention, the light-emitting diode package further includes a first conductive through hole. The first conductive through hole penetrates a surface of the first dielectric layer facing the redistribution layer. The first conductive through hole is connected to the redistribution layer and the light-emitting diode.

In an embodiment of the invention, the light-emitting diode package further includes a circuit board and a conductive terminal. The circuit board has a first surface and a second surface opposite to the first surface, and the redistribution layer is disposed on the second surface of the circuit board. The conductive terminal is disposed on the second surface of the circuit board. The conductive terminal is connected to the circuit board and the redistribution layer.

In an embodiment of the invention, the light-emitting diode package further includes an electronic element. The electronic element is disposed on the first surface of the circuit board and electrically connected to the light-emitting diode.

In an embodiment of the invention, the redistribution layer includes at least one conductive layer, at least one second dielectric layer, and at least one conductive hole. The conductive layer and the second dielectric layer are sequentially stacked on the first dielectric layer. The conductive hole penetrates the second dielectric layer. The conductive hole is electrically connected to the conductive layer.

In an embodiment of the invention, the circuit board includes a core layer, a first build-up circuit structure, a second build-up circuit structure, and a second conductive through hole. The first build-up circuit structure and the second build-up circuit structure are respectively disposed at two opposite sides of the core layer. The second conductive through hole penetrates the core layer. The second conductive through hole is electrically connected to the first build-up circuit structure and the second build-up circuit structure.

A manufacturing method of a light-emitting diode package of the invention includes the following steps. First, a light-emitting diode is formed on a first temporary substrate. In particular, the light-emitting diode includes a first light-emitting diode, a second light-emitting diode, and a third light-emitting diode. Next, a first dielectric layer is formed on the first temporary substrate to cover the light-emitting diode. Next, a redistribution layer is formed on a surface of the first dielectric layer to be electrically connected to the light-emitting diode. Next, a second temporary substrate is provided, and the redistribution layer is bonded onto the second temporary substrate. Then, the first temporary substrate is removed to expose the light-emitting diode and the first dielectric layer. Next, a plurality of wavelength conversion structures are formed on the second light-emitting diode and the third light-emitting diode so that the plurality of wavelength conversion structures are respectively in contact with the second light-emitting diode and the third light-emitting diode. Then, the second temporary substrate is removed.

In an embodiment of the invention, the manufacturing method of the light-emitting diode package further includes: forming a first conductive through hole penetrating the surface of the first dielectric layer and connected to the redistribution layer and the light-emitting diode.

In an embodiment of the invention, the manufacturing method of the light-emitting diode package further includes: providing a circuit board, and bonding the redistribution layer onto the circuit board. In particular, the circuit board has a first surface and a second surface opposite to the first surface. The redistribution layer is disposed on the second surface of the circuit board. The light-emitting diode and the first dielectric layer are disposed on the redistribution layer; and a conductive terminal is formed to be connected to the circuit board and the redistribution layer.

In an embodiment of the invention, the manufacturing method of the light-emitting diode package further includes: disposing an electronic element on the first surface of the circuit board to be electrically connected to the light-emitting diode.

In an embodiment of the invention, a method of forming the light-emitting diode is an epitaxy growth method.

Based on the above, in the light-emitting diode package and the manufacturing method thereof of the present embodiment, the light-emitting diode is formed on the first temporary substrate first by, for example, an epitaxy growth method, and the first dielectric layer and the redistribution layer are directly manufactured on the light-emitting diode. As a result, mass transfer and encapsulation gel processes may be omitted, so that the light-emitting diode package and the manufacturing method thereof of the present embodiment may be applied to the micro light-emitting diode package. In addition, since the redistribution layer is manufactured from the light-emitting diode end, the issue of die shift caused by the current use of pick-and-place may be avoided, and therefore the process may be simplified. Moreover, the step of removing the first temporary substrate may avoid the issue of optical interference in the subsequently formed light-emitting diode package due to the light guiding characteristics of sapphire.

In order to make the aforementioned features and advantages of the disclosure more comprehensible, embodiments accompanied with figures are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 to FIG. 13 show schematic cross-sectional views of a manufacturing method of a light-emitting diode package of an embodiment of the invention.

### DESCRIPTION OF THE EMBODIMENTS

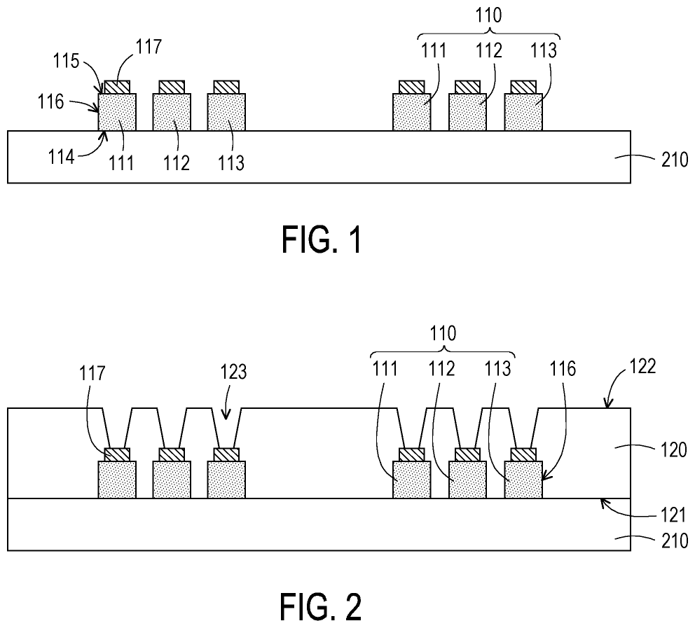

FIG. 1 to FIG. 13 show schematic cross-sectional views of a manufacturing method of a light-emitting diode package of an embodiment of the invention. In the present embodiment, the manufacturing method of a light-emitting diode package 100, for example, adopts a fan-out panel level package (FOPLP) and a die first/face up manufacturing method, and the manufacturing method of the light-emitting diode package 100 may include, but is not limited to, the following steps:

First, referring to FIG. 1, a light-emitting diode 110 is formed on a first temporary substrate 210. Specifically, the light-emitting diode 110 may be formed on the first temporary substrate 210 by, for example, an epitaxy growth method, but the invention is not limited thereto. The light-emitting diode 110 of the present embodiment is disposed on the first temporary substrate 210 in an array arrangement, for example, but the invention is not limited thereto. The light-emitting diode 110 includes a first light-emitting diode 111, a second light-emitting diode 112, and a third light-emitting diode 113. The light-emitting diode 110 is, for example, a micro light-emitting diode (μLED), but the invention is not limited thereto. For example, the first light-emitting diode 111, the second light-emitting diode 112, and the third light-emitting diode 113 are, for example, micro light-emitting diodes that may emit blue light, but the invention is not limited thereto. Moreover, the light-emitting diode 110 may have a surface 114, a surface 115 opposite to the surface 114, a side surface 116 connected to the surface 114 and the surface 115, and an electrode 117 (the cross-section of FIG. 1 schematically shows only one of the electrodes of the light-emitting diode 110, and another electrode of the light-emitting diode 110 is in the other cross-sections). The surface 114 may be in contact with the first temporary substrate 210 and be coplanar with the surface in contact with the first temporary substrate 210. The electrode 117 may be disposed on the surface 115. The first temporary substrate 210 and the electrode 117 may be located at two opposite sides of the light-emitting diode 110 respectively. In the present embodiment, the light-emitting diode 110 is implemented as a horizontal light-emitting diode, but the invention is not limited thereto. When the light-emitting diode 110 is a thin-film micro-light-emitting diode, the light-emitting diode 110 may have a thickness of, for example, within 7 micrometers (μm). The first temporary substrate 210 may be a native epitaxy sapphire substrate, such as a sapphire substrate, but the invention is not limited thereto. The thickness of the first temporary substrate 210 may be, for example, 50 micrometers or more, but the invention is not limited thereto.

Next, referring to FIG. 2, a first dielectric layer 120 is formed on the first temporary substrate 210 to cover the light-emitting diode 110. The first dielectric layer 120 may be disposed between the first light-emitting diode 111, the second light-emitting diode 112, and the third light-emitting diode 113. The first dielectric layer 120 may cover the first temporary substrate 210 exposed by the light-emitting diode 110. The first dielectric layer 120 may be in contact with the side surface 116 of the light-emitting diode 110. The first dielectric layer 120 may have a surface 121, a surface 122 opposite to the surface 121, and a plurality of openings 123. The surface 121 may be in contact with the first temporary substrate 210. The openings 123 may expose the electrode 117 of the light-emitting diode 110. In the present embodiment, the material of the first dielectric layer 120 may be, for example, a photoimageable dielectric (PID), but the invention is not limited thereto.

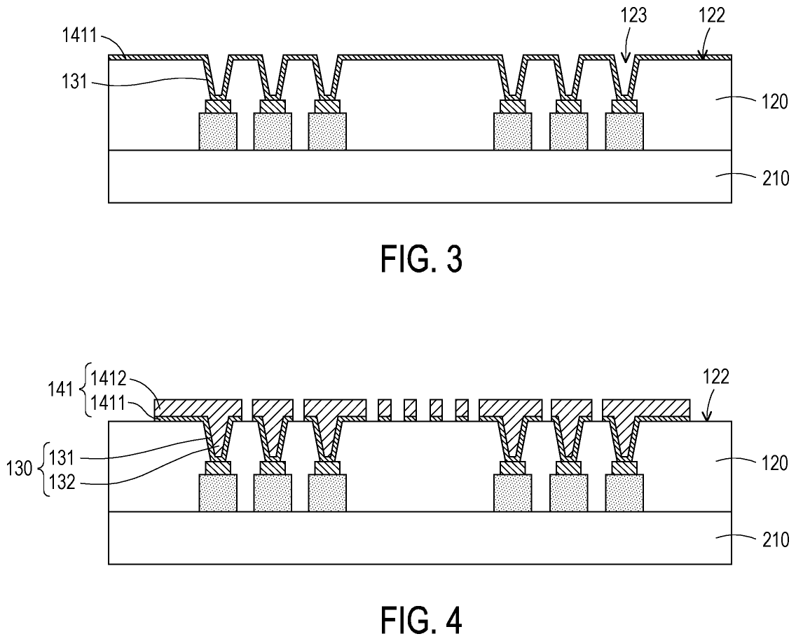

Next, referring to FIG. 3 and FIG. 4, a first conductive through hole 130 is formed to penetrate the surface of the first dielectric layer 120 facing away from the first temporary substrate 210 and be connected to the redistribution layer 140 and the light-emitting diode 110. Specifically, a seed layer 131 is formed in the openings 123 of the first dielectric layer 120 first, and a seed layer 1411 is formed on the surface 122 of the first dielectric layer 120. The seed layers 131 and 1411 may include a titanium layer and a copper layer located on the titanium layer. The seed layers 131 and 1411 may be formed by, for example, a sputtering method, but the invention is not limited thereto. Next, a conductive material layer 132 is formed in the openings 123, and a conductive material layer 1412 is formed on the seed layer 1411, and a portion of the seed layer 1411 (not shown) is exposed. Next, the portion of the seed layer 1411 exposed by the conductive material layer 1412 is removed to expose a portion of the surface 122 and form the first conductive through hole 130 and the conductive layer 141 of the redistribution layer 140. In particular, the first conductive through hole 130 may be defined by the conductive material layer 132 and the seed layer 131 disposed in the openings 123, and the conductive layer 141 may be defined by the conductive material layer 1412 disposed on the surface 122 and the seed layer 1411 covered by the conductive material layer 1412.

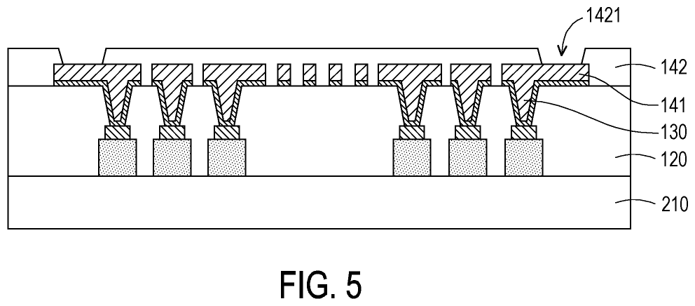

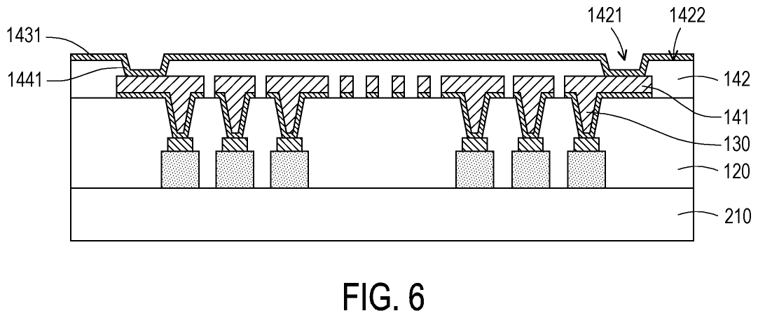

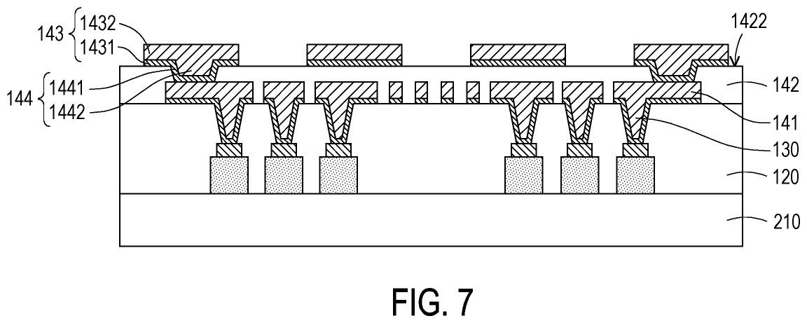

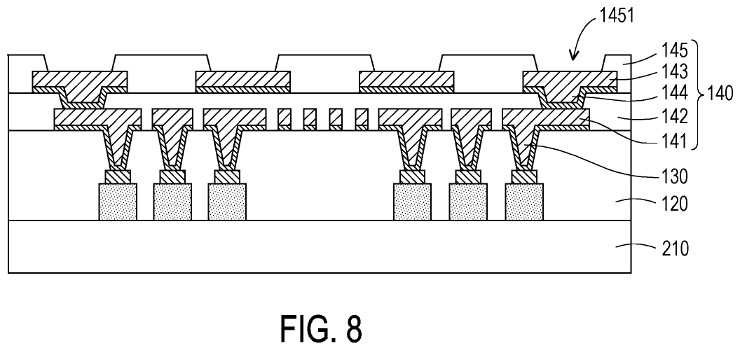

Next, referring to FIG. 5 to FIG. 8, the redistribution layer 140 is formed on the surface 122 of the first dielectric layer 120. Specifically, as shown in FIG. 5, the second dielectric layer 142 is first formed on the conductive layer 141 to cover the first dielectric layer 120 and the conductive layer 141. In particular, the second dielectric layer 142 has an opening 1421 to expose a portion of the conductive layer 141. Next, as shown in FIG. 6, a seed layer 1431 is formed on a surface 1422 of the second dielectric layer 142, and a seed layer 1441 is formed in the opening 1421 of the second dielectric layer 142. The seed layers 1431 and 1441 may include a titanium layer and a copper layer located on the titanium layer. The seed layers 1431 and 1441 may be formed by, for example, a sputtering method, but the invention is not limited thereto. Next, as shown in FIG. 7, a conductive material layer 1432 is formed on a portion of the surface 1422, and a conductive material layer 1442 is formed in the opening 1421 to expose a portion of the seed layer 1431. Next, the portion of the seed layer 1431 exposed by the conductive material layer 1432 is removed to expose a portion of the surface 1422 and form a conductive hole 144 and a conductive layer 143. In particular, the conductive hole 144 may be defined by the conductive material layer 1442 and the seed layer 1441 disposed in the opening 1421, and the conductive layer 143 may be defined by the conductive material layer 1432 disposed on the surface 1422 and the seed layer 1431 covered by the conductive material layer 1432. Next, as shown in FIG. 8, a second dielectric layer 145 is formed on the conductive layer 143 to cover the second dielectric layer 142 and the conductive layer 143. In particular, the second dielectric layer 145 has an opening 1451 to expose a portion of the conductive layer 143. At this point, the redistribution layer 140 of the present embodiment is substantially completed.

In the present embodiment, the redistribution layer 140 may include the conductive layer 141, the second dielectric layer 142, the conductive layer 143, the second dielectric layer 145, and the conductive hole 144. In particular, the conductive layers 141 and 143 and the second dielectric layers 142 and 145 are sequentially stacked on the first dielectric layer 120, the conductive hole 144 penetrates the second dielectric layer 145, and the conductive hole 144 is electrically connected to the conductive layer 141 and the conductive layer 143. In particular, the spacing between two adjacent pads in the conductive layer 143 is greater than the spacing between two adjacent pads in the conductive layer 141, and the spacing between two adjacent pads in the conductive layer 141 is greater than the spacing between two adjacent light-emitting diodes 110 (that is, the spacing between the first light-emitting diode 111 and the second light-emitting diode 112, or the spacing between the second light-emitting diode 112 and the third light-emitting diode 113). Moreover, although the redistribution layer 140 of the present embodiment may include two conductive layers and two dielectric layers, the invention does not limit the number of conductive layers and dielectric layers in the redistribution layer.

It should be mentioned that, in the present embodiment, after the light-emitting diode 110 is formed on the first temporary substrate 210, by directly manufacturing the first dielectric layer 120 and the redistribution layer 140 on the resulting light-emitting diode 110, mass transfer and encapsulation gel processes may be omitted. As a result, the manufacturing method of the present embodiment may be applicable to micro light-emitting diode packaging and the issue of die shift may be avoided (mainly since the micro light-emitting diode GaN epitaxy thin film itself is still bonded to sapphire in a monocrystalline manner at this time, and therefore this strong bonding substantially does not have any nano-level die shift). Therefore, the effect of simplifying the process is achieved.

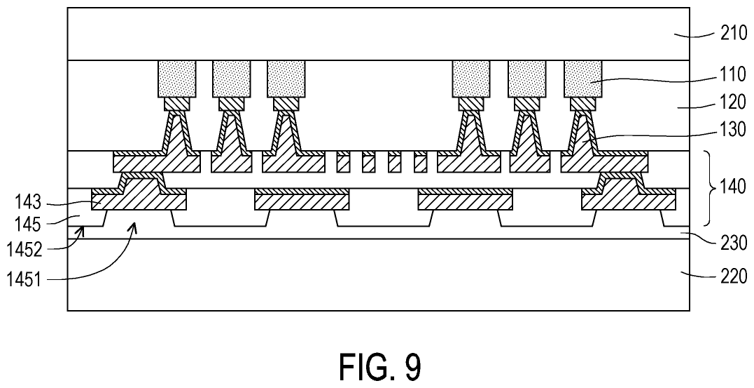

Next, referring to FIG. 9, a second temporary substrate 220 is provided, and the redistribution layer 140 is bonded onto the second temporary substrate 220. Specifically, an adhesive material layer 230 is first disposed on the second temporary substrate 220. Next, the entire structure (including at least the light-emitting diode 110, the first dielectric layer 120, the first conductive through hole 130, and the redistribution layer 140) together with the first temporary substrate 210 are turned upside down, so that the redistribution layer 140 may be bonded onto the second temporary substrate 220 via the adhesive material layer 230. At this point, the adhesive material layer 230 may be disposed on a surface 1452 of the second dielectric layer 145 and filled into the opening 1451, the light-emitting diode 110 and the first dielectric layer 120 may be disposed on the redistribution layer 140, and the second temporary substrate 220 and the first temporary substrate 210 may be respectively located at two opposite sides of the entire structure. In the present embodiment, the adhesive material layer 230 is, for example, wax, and the second temporary substrate 220 is, for example, glass, but the invention is not limited thereto.

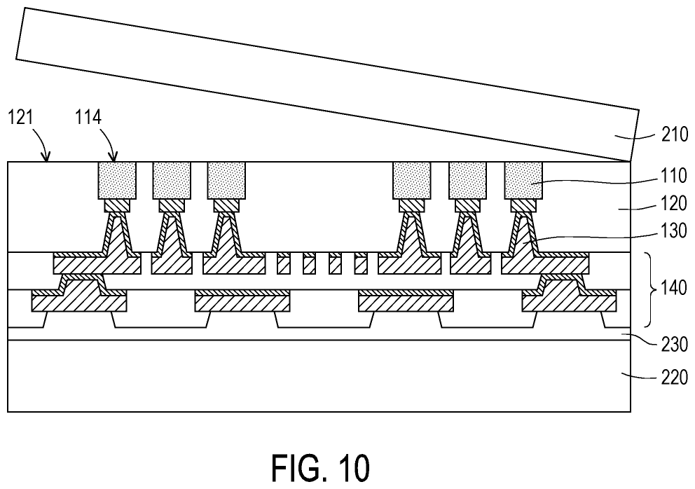

Next, referring to FIG. 10, the first temporary substrate 210 is removed to expose the surface 114 of the light-emitting diode 110 and the surface 121 of the first dielectric layer 120. In the present embodiment, the first temporary substrate 210 may be removed by, for example, a laser lift-off (LLO) method, but the invention is not limited thereto. In the present embodiment, when the material of the first temporary substrate 210 is sapphire, the step of removing the first temporary substrate 210 may avoid the issue of optical interference in the subsequently formed light-emitting diode package due to the light guiding characteristics of sapphire.

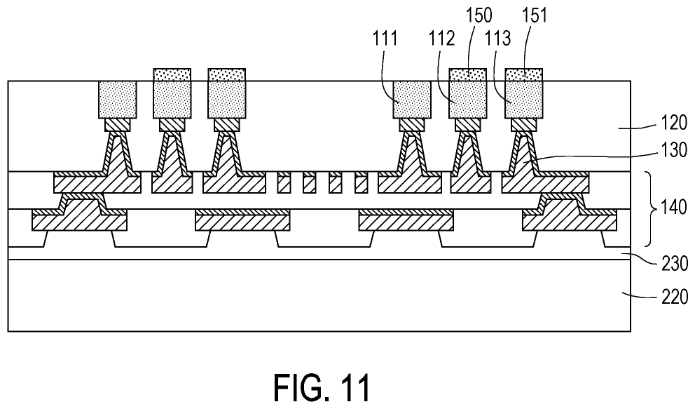

Next, referring to FIG. 11, a plurality of wavelength conversion structures 150 and 151 are formed on the surface 121 of the first dielectric layer 120, so that the wavelength conversion structure 150 and the wavelength conversion structure 151 may be in contact with the second light-emitting diode 112 and the third light-emitting diode 113, respectively. Specifically, the wavelength conversion structure 150 is disposed corresponding to the second light-emitting diode 112, and the wavelength conversion structure 151 is disposed corresponding to the third light-emitting diode 113. The wavelength conversion structure 150 and the wavelength conversion structure 151 may be disposed on the second light-emitting diode 112 and the third light-emitting diode 113 by using micro nozzles, but the invention is not limited thereto. In the present embodiment, the material of the wavelength conversion structures 150 and 151 may be, for example, a quantum dot (QD) or other materials that may convert the wavelength of incident light into another wavelength, but the invention is not limited thereto. For example, when the second light-emitting diode 112 and the third light-emitting diode 113 are micro light-emitting diodes that may emit blue light, the wavelength conversion structure 150 may be a red quantum dot to convert the wavelength of incident light into the wavelength of red light, and the wavelength conversion structure 151 may be a green quantum dot to convert the wavelength of incident light into the wavelength of green light. A photoluminescence mechanism is mainly used to achieve RGB wavelength to form white light.

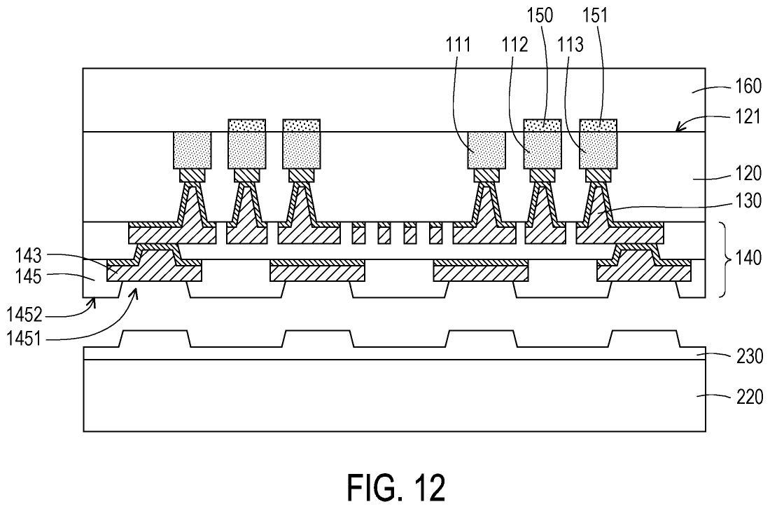

Next, referring to FIG. 12, first, a transparent encapsulant 160 is formed on the surface 121 of the first dielectric layer 120 to cover the plurality of wavelength conversion structures 150 and 151 and cover the surface 121 of the first dielectric layer 120. In particular, a bottom surface of the transparent encapsulant 160 is coplanar with the surface 121 and the surface 114. In particular, the transparent encapsulant 160 may be in contact with the first light-emitting diode 111 and a portion of the first dielectric layer 120. The material of the transparent encapsulant 160 may be, for example, epoxy, but the invention is not limited thereto. Then, the second temporary substrate 220 and the adhesive material layer 230 are removed to expose the opening 1451 and a portion of the conductive layer 143. In the present embodiment, the second temporary substrate 220 and the adhesive material layer 230 may be removed by, for example, a laser lift-off (LLO) method, but the invention is not limited thereto.

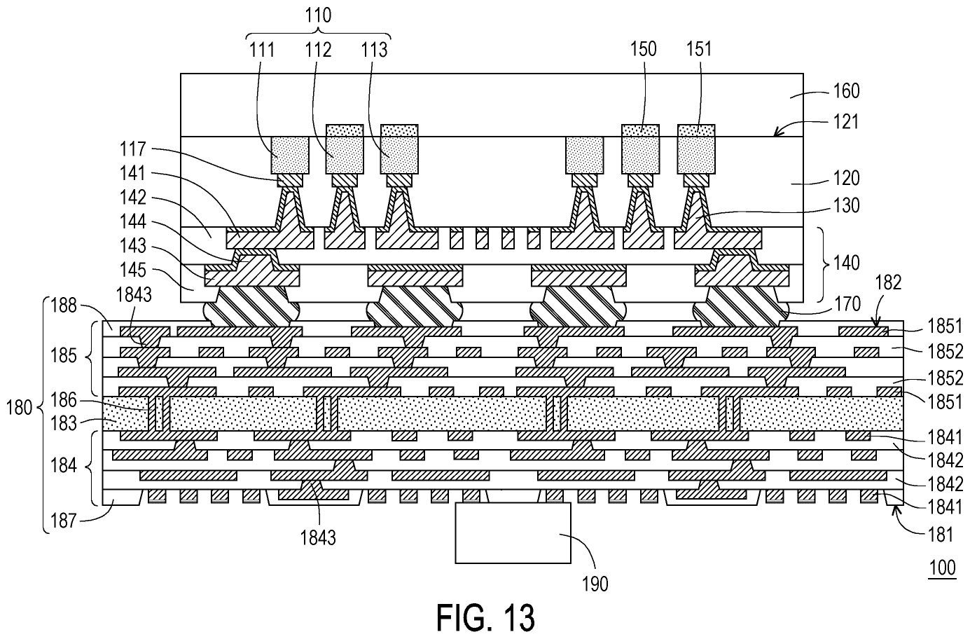

Next, referring to FIG. 13, a conductive terminal 170 is first formed on the surface 1452 of the second dielectric layer 145 and in the opening 1451 so that the conductive terminal 170 may be in contact with a portion of the conductive layer 143. Next, a circuit board 180 is provided, and the redistribution layer 140 may be bonded onto the circuit board 180 via the conductive terminal 170. In particular, the circuit board 180 has a first surface 181 and a second surface 182 opposite to the first surface 181. The redistribution layer 140 may be disposed on the second surface 182 of the circuit board 180. The conductive terminal 170 may be connected to the circuit board 180 and the redistribution layer 140. The conductive terminal 170 is, for example, a solder ball, but the invention is not limited thereto.

Specifically, the circuit board 180 may include a core layer 183, a first build-up circuit structure 184, a second build-up circuit structure 185, a second conductive through hole 186, and solder masks 187 and 188. The first build-up circuit structure 184 and the second build-up circuit structure 185 are respectively disposed at two opposite sides of the core layer 183. The second conductive through hole 186 penetrates the core layer 183. The second conductive through hole 186 is electrically connected to the first build-up circuit structure 184 and the second build-up circuit structure 185.

The first build-up circuit structure 184 may include a conductive layer 1841, a dielectric layer 1842, and a conductive hole 1843. In particular, the conductive layer 1841 and the dielectric layer 1842 are sequentially stacked on one side of the core layer 183, the conductive hole 1843 penetrates the dielectric layer 1842, and the conductive hole 1843 is electrically connected to the conductive layer 1841. The second build-up circuit structure 185 may include a conductive layer 1851, a dielectric layer 1852, and a conductive hole 1853. In particular, the conductive layer 1851 and the dielectric layer 1852 are sequentially stacked on another side of the core layer 183, the conductive hole 1853 penetrates the dielectric layer 1852, and the conductive hole 1853 is electrically connected to the conductive layer 1851.

The solder mask 187 is disposed on the first build-up circuit structure 184 to cover the outermost dielectric layer 1842 (that is, the dielectric layer 1842 in the first build-up circuit structure 184 farthest from the core layer 183) and expose a portion of the outermost conductive layer 1841 (that is, the conductive layer 1841 in the first build-up circuit structure 184 farthest from the core layer 183). The solder mask 188 is disposed on the second build-up circuit structure 185 to cover the outermost dielectric layer 1852 (that is, the dielectric layer 1852 in the second build-up circuit structure 185 farthest from the core layer 183) and expose a portion of the outermost conductive layer 1851 (that is, the conductive layer 1851 in the second build-up circuit structure 185 farthest from the core layer 183). In particular, the conductive terminal 170 may be in contact with a portion of the outermost conductive layer 1851 exposed by the solder mask 188.

Next, an electronic element 190 is disposed on the first surface 181 of the circuit board 180 so that the electronic element 190 may be electrically connected to the light-emitting diode 110 via the circuit board 180, the conductive terminal 170, the redistribution layer 140, and the first conductive through hole 130. In particular, the electronic element 190 may be in contact with a portion of the outermost conductive layer 1841 exposed by the solder mask 187. The electronic element 190 may be, for example, a driver IC, but the invention is not limited thereto. At this point, the light-emitting diode package 100 of the present embodiment is substantially completed.

In short, the light-emitting diode package 100 of the present embodiment may include the circuit board 180, the redistribution layer 140, the light-emitting diode 110, the first dielectric layer 120, and the plurality of wavelength conversion structures 150 and 151. The circuit board 180 has the first surface 181 and the second surface 182 opposite to the first surface 181. The redistribution layer 140 is disposed on the second surface 182 of the circuit board 180. The light-emitting diode 110 is disposed on the redistribution layer 140 and includes the first light-emitting diode 111, the second light-emitting diode 112, and the third light-emitting diode 113. The first dielectric layer 120 is disposed on the redistribution layer 140 and covers the light-emitting diode 110. The plurality of wavelength conversion structures 150 and 151 are disposed on the first dielectric layer 120 and respectively in contact with the second light-emitting diode 112 and the third light-emitting diode 113.

Based on the above, in the light-emitting diode package and the manufacturing method thereof of the present embodiment, by directly manufacturing the first dielectric layer and the redistribution layer on the resulting light-emitting diode, mass transfer and encapsulation gel processes may be omitted. Therefore, the light-emitting diode package and the manufacturing method thereof of the present embodiment may be applied to micro light-emitting diode packaging, and the issue of die shift may be avoided, thereby achieving the effect of simplifying the process. Moreover, the step of removing the first temporary substrate may avoid the issue of optical interference in the subsequently formed light-emitting diode package due to the light guiding characteristics of sapphire.

Moreover, the wavelength conversion structures are formed on the epitaxy thin film of the light-emitting diode (for example, a micro light-emitting diode), and the final light-emitting diode package (as shown in FIG. 13) does not have a native epitaxy sapphire substrate (that is, the first temporary substrate), which is a change in characteristic structural appearance. Therefore, compared with the current sub-millimeter light-emitting diode (mini LED) or micro light-emitting diode package (μLED), both of which have a native epitaxy substrate to be used with PoP package-on-package or other mass transfer processes, since the light-emitting diode package of the invention does not have a native epitaxy substrate, the overall thickness may be significantly reduced. Moreover, compared with the current PoP package-on-package or mass transfer process in which there is an alignment issue for electrical connection, in the invention, the redistribution layer is completed before the light-emitting diode (for example, a thin-film micro light-emitting diode) is transferred to the circuit board, and therefore there is no alignment issue.

Although the invention has been described with reference to the above embodiments, it will be apparent to one of ordinary skill in the art that modifications to the described embodiments may be made without departing from the spirit of the disclosure. Accordingly, the scope of the disclosure is defined by the attached claims not by the above detailed descriptions.

What is claimed is:

1. A light-emitting diode package, comprising:
a redistribution layer;
a light-emitting diode disposed on the redistribution layer and electrically connected to the redistribution layer, wherein the light-emitting diode comprises a first light-emitting diode, a second light-emitting diode, and a third light-emitting diode;
a first dielectric layer disposed on the redistribution layer and covering the light-emitting diode;
a plurality of wavelength conversion structures disposed on the second light-emitting diode and the third light-emitting diode and respectively in contact with the second light-emitting diode and the third light-emitting diode; and
a transparent encapsulant disposed on the first dielectric layer and covering the plurality of wavelength conversion structures.

2. The light-emitting diode package of claim 1, wherein the light-emitting diode package does not have a native epitaxy substrate.

3. The light-emitting diode package of claim 1, further comprising:
a first conductive through hole penetrating a surface of the first dielectric layer facing the redistribution layer and connected to the redistribution layer and the light-emitting diode.

4. The light-emitting diode package of claim 1, further comprising:
a circuit board having a first surface and a second surface opposite to the first surface, and the redistribution layer is disposed on the second surface of the circuit board; and
a conductive terminal disposed on the second surface of the circuit board and connected to the circuit board and the redistribution layer.

5. The light-emitting diode package of claim 4, further comprising:
an electronic element disposed on the first surface of the circuit board and electrically connected to the light-emitting diode.

6. The light-emitting diode package of claim 4, wherein the circuit board comprises a core layer, a first build-up circuit structure, a second build-up circuit structure, and a second conductive through hole, the first build-up line structure and the second build-up line structure are respectively disposed at two opposite sides of the core layer, the second conductive through hole penetrates the core layer, and the second conductive through hole is electrically connected to the first build-up circuit structure and the second build-up circuit structure.

7. The light-emitting diode package of claim 1, wherein the redistribution layer comprises at least one conductive layer, at least one second dielectric layer, and at least one conductive hole, the at least one conductive layer and the at least one second dielectric layer are sequentially stacked on the first dielectric layer, the at least one conductive hole penetrates the second dielectric layer, and the at least one conductive hole is electrically connected to the at least one conductive layer.

8. A manufacturing method of a light-emitting diode package, comprising:
forming a light-emitting diode on a first temporary substrate, wherein the light-emitting diode comprises a first light-emitting diode, a second light-emitting diode, and a third light-emitting diode;
forming a first dielectric layer on the first temporary substrate to cover the light-emitting diode;
forming a redistribution layer on a surface of the first dielectric layer to be electrically connected to the light-emitting diode;
providing a second temporary substrate, and bonding the redistribution layer onto the second temporary substrate;
removing the first temporary substrate to expose the light-emitting diode and the first dielectric layer;
forming a plurality of wavelength conversion structures on the second light-emitting diode and the third light-emitting diode so that the plurality of wavelength conversion structures are respectively in contact with the second light-emitting diode and the third light-emitting diode;
forming a transparent encapsulant on the first dielectric layer to cover the plurality of wavelength conversion structures; and
removing the second temporary substrate.

9. The manufacturing method of the light-emitting diode package of claim 8, further comprising:
forming a first conductive through hole penetrating the surface of the first dielectric layer and connected to the redistribution layer and the light-emitting diode.

10. The manufacturing method of the light-emitting diode package of claim 8, further comprising:
providing a circuit board, wherein the circuit board has a first surface and a second surface opposite to the first surface, the redistribution layer is disposed on the second surface of the circuit board, and the light-emitting diode and the first dielectric layer are disposed on the redistribution layer; and
forming a conductive terminal to be connected to the circuit board and the redistribution layer.

11. The manufacturing method of the light-emitting diode package of claim 10, further comprising:
configuring an electronic element on the first surface of the circuit board to be electrically connected to the light-emitting diode.

12. The manufacturing method of the light-emitting diode package of claim 8, wherein a method of forming the light-emitting diode is an epitaxy growth method.
